(19) United States
(12) Patent Application Publication
(10) Pub. No.: US 2023/0339509 A1
(43) Pub. Date: Oct. 26, 2023

(54) PULL-OVER SITE SELECTION

(71) Applicant: GM CRUISE HOLDINGS LLC, SAN FRANCISCO, CA (US)

(72) Inventors: Jeremy Allan, Menlo Park, CA (US); Adrian Kit Malaran, San Francisco, CA (US); Vivek Nagraj Rangaswamy, Oakland, CA (US); Alexander Dean Hertzberg, Berkeley, CA (US); Carl Axel Aadne Folkestad, San Francisco, CA (US); Allen Tang, Millbrae, CA (US)

(73) Assignee: GM CRUISE HOLDINGS LLC, SAN FRANCISCO, CA (US)

(21) Appl. No.: 17/725,602

(22) Filed: Apr. 21, 2022

(51) Int. Cl. B60W 60/00; G07C 5/00; G06F 30/27

(52) U.S. Cl. CPC B60W 60/00253; G07C 5/008; G06F 30/27; B60W 2556/45

(57) ABSTRACT

Techniques and mechanisms for pull-over site selection for an autonomous vehicle. Simulation information is received from an external source. The simulation information corresponds to multiple simulations involving a virtual autonomous vehicle and available pull-over locations for the virtual autonomous vehicle. An indication to cause the autonomous vehicle to search for a pull-over location is received. Potential pull-over locations are analyzed in response to the indication. The potential pull-over locations are compared to simulated pull-over locations to identify a selected pull-over location. The autonomous vehicle navigates the selected pull-over location. The autonomous vehicle stops at the selected pull-over location.

### TECHNICAL FIELD

Examples provided herein relate to control of autonomous vehicles (AVs). More particularly, examples provided herein relate to use of multi-agent simulation and learning approaches to support selection of optimal pull-over locations for an AV.

### BACKGROUND

Autonomous vehicles, also known as self-driving cars, driverless vehicles, and robotic vehicles, may be vehicles that use multiple sensors to sense the environment and move without human input. Automation technology in the autonomous vehicles may enable the vehicles to drive on roadways and to accurately and quickly perceive the vehicle's environment, including obstacles, signs, and traffic lights. Autonomous technology may utilize map data that can include geographical information and semantic objects (such as parking spots, lane boundaries, intersections, crosswalks, stop signs, traffic lights) for facilitating driving safety. The vehicles can be used to pick up passengers and drive the passengers to selected destinations. The vehicles can also be used to pick up packages and/or other goods and deliver the packages and/or goods to selected destinations.

### BRIEF DESCRIPTION OF THE DRAWINGS

To easily identify the discussion of any particular element or act, the most significant digit or digits in a reference number refer to the figure number in which that element is first introduced.

FIG. 1 is a block diagram of an example autonomous vehicle.

FIG. 2 is an example environment in which an autonomous vehicle may select a pull-over location to pick up a passenger.

FIG. 3 is an example environment in which an autonomous vehicle may select a pull-over location to drop off a passenger.

FIG. 4 is a block diagram of a simulation environment that can provide simulation information to an autonomous vehicle for assistance in selection of pull-over locations.

FIG. 5 is a flow diagram for one technique for selection of a pull-over location for an autonomous vehicle.

FIG. 6 is a block diagram of one example of a processing system that can provide selection of a pull-over location for an autonomous vehicle.

### DETAILED DESCRIPTION

There are many scenarios where an autonomous vehicle may be required to find a location to pull over. For example, if the autonomous vehicle is providing a ride sharing service, the autonomous vehicle will navigate to a location where a passenger is waiting and will find a location to stop so that the passenger can get in the autonomous vehicle. Similarly, the autonomous vehicle will navigate to a drop off location and will find a location to stop so that the passenger can exit the autonomous vehicle. As another example, the autonomous vehicle can provide a delivery service where cargo is picked up and dropped off at various locations, and the autonomous vehicle will navigate to a pickup or drop off location and find a place to stop so that cargo can be deposited into the autonomous vehicle and/or removed from the autonomous vehicle.

One solution to pull-over location selection is to stop in the lane of traffic closest to the side of the road corresponding to the pick up/drop off location. This solution may be satisfactory in certain circumstances (e.g., one-lane road, no traffic, traffic not flowing). However, in many circumstances this is not an optimal solution because it can stop traffic, for example. Another solution is to find a pull-over location out of the flow of traffic. This may be an option in some circumstances, but may not be available in other circumstances (e.g., all parking spots are occupied, stopping/parking is not allowed, possible pull-over locations may not be identified using simplistic analysis by the autonomous vehicle).

Thus, the determination of an optimal pull-over location may be a complex decision and may be dynamically changing (e.g., based on traffic conditions, traffic rules and time of day, location of a possibly moving passenger). Evaluation of these dynamically changing conditions and decision making based on the evaluations performed in real time by the autonomous vehicle can require large amounts of processing power and other resources which may not be available. In examples described herein, offline simulations can be performed to provide, for example, a trained artificial neural network with weights based on the simulations that can be used by the autonomous vehicle for operation including selecting pull-over locations.

In some examples, the simulations can be multi-agent simulations that not only simulate actions of the autonomous vehicle with respect to other road users (e.g., vehicles, bicycles, pedestrians), but also passengers and/or potential passengers of the autonomous vehicle. Thus, simulations can be used to train the artificial neural network that is deployed to the autonomous vehicle based on the training from the simulation. For example, the simulation generates the data to use for training to find the weights for the artificial neural network that will control the autonomous vehicle in the real world.

In some examples, the simulations are based on reinforcement learning (RL) techniques. Reinforcement learning is a type of machine learning (ML) that focuses on how intelligent agents (e.g., autonomous vehicles) ought to behave in their environments to optimize/maximize results (e.g., should an autonomous vehicle yield to another vehicle, should a delivery be allowed). Reinforcement learning differs from supervised learning in that it does not require labeled input/output pairs and does not require that sub-optimal results be explicitly corrected. In contrast to supervised learning, reinforcement learning finds a balance between established knowledge and novel conditions. Reinforcement learning differs from unsupervised learning where an internal representation is developed through mimicry.

Various reinforcement learning techniques can be utilized including, for example, Monte Carlo, Q-learning, state-action-reward-state-action (SARSA), deep Q learning, double Q learning, deep deterministic policy gradient, asynchronous advantage actor-critic, proximal policy optimization, soft actor-critic, etc. Large numbers of simulations can be performed to off line to provide a trained artificial neural network to the autonomous vehicle for real world operation. For example, in simulations, many different pull-over locations can be selected and simulated and the effects on the surrounding operating environment (e.g., changes to traffic flow, how far the passenger will have to move to get in to, or out of, the autonomous vehicle, whether parked vehicles will be blocked) can be simulated. The autonomous vehicle can look for and select a pull-over location that is most similar to what the closest simulation determined was the best pull-over location. This can be accomplished by a scoring-based comparison, for example.

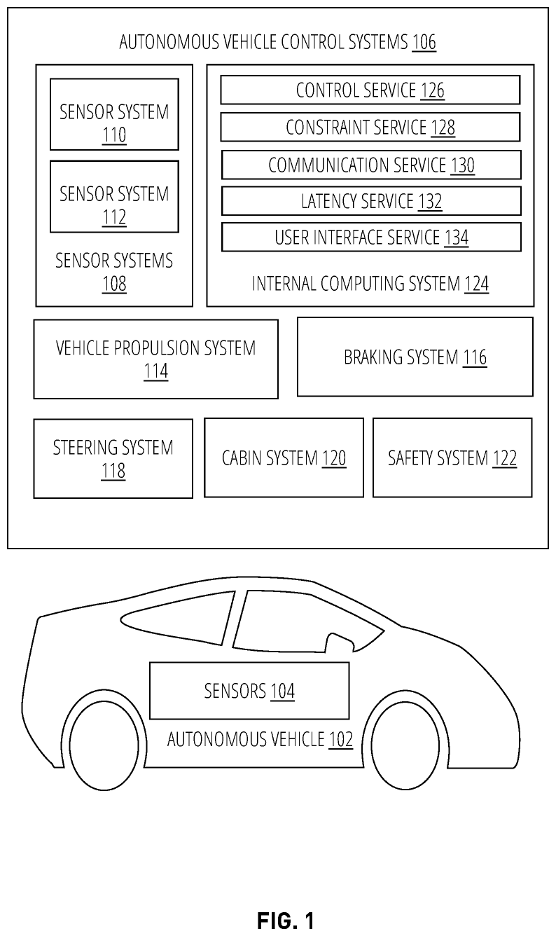

FIG. 1 is a block diagram of an example autonomous vehicle. Autonomous vehicle 102 has the functionality to navigate roads without a human driver by utilizing sensors 104 and autonomous vehicle control systems 106.

Autonomous vehicle 102 can include, for example, sensor systems 108 including any number of sensor systems (e.g., sensor system 110, sensor system 112). Sensor systems 108 can include various types of sensors that can be arranged throughout autonomous vehicle 102. For example, sensor system 110 can be a camera sensor system. As another example, sensor system 112 can be a light detection and ranging (LIDAR) sensor system. As a further example, one of sensor systems 108 can be a radio detection and ranging (RADAR) sensor system, an electromagnetic detection and ranging (EmDAR) sensor system, a sound navigation and ranging (SONAR) sensor system, a sound detection and ranging (SODAR) sensor system, a global navigation satellite system (GNSS) receiver system, a global positioning system (GPS) receiver system, accelerometers, gyroscopes, inertial measurement unit (IMU) systems, infrared sensor systems, laser rangefinder systems, microphones, etc.

Autonomous vehicle 102 can use one or more sensors of sensor systems 108 to evaluate the operating environment and selected a pull-over location using the approach described herein. Autonomous vehicle 102 can then use the various control systems to navigate to the pull-over location and stop to allow a passenger to enter and/or exit (or in a delivery scenario allow cargo to be loaded or unloaded).

Autonomous vehicle 102 can further include mechanical systems to control and manage motion of autonomous vehicle 102. For example, the mechanical systems can include vehicle propulsion system 114, braking system 116, steering system 118, cabin system 120 and safety system 122. Vehicle propulsion system 114 can include, for example, an electric motor, an internal combustion engine, or both. Braking system 116 can include an engine brake, brake pads, actuators and/or other components to control deceleration of autonomous vehicle 102. Steering system 118 can include components that control the direction of autonomous vehicle 102. Cabin system 120 can include, for example, cabin temperature control systems, in-cabin infotainment systems and other internal elements.

Safety system 122 can include various lights, signal indicators, airbags, systems that detect and react to other vehicles. Safety system 122 can include one or more radar systems. Autonomous vehicle 102 can utilize different types of radar systems, for example, long-range radar (LRR), mid-range radar (MRR) and/or short-range radar (SRR). LRR systems can be used, for example, to detect objects that are farther away (e.g., 200 meters, 300 meters) from the vehicle transmitting the signal. LRR systems can operate in the 77 GHz band (e.g., 76-81 GHz). SRR systems can be used, for example, for blind spot detection or collision avoidance. SRR systems can operate in the 24 GHz band. MRR systems can operate in either the 24 GHz band or the 77 GHz band. Other frequency bands can also be supported.

Autonomous vehicle 102 can further include internal computing system 124 that can interact with sensor systems 108 as well as the mechanical systems (e.g., vehicle propulsion system 114, braking system 116, steering system 118, cabin system 120 and safety system 122). Internal computing system 124 includes at least one processor and at least one memory system that can store executable instructions to be executed by the processor. Internal computing system 124 can include any number of computing sub-systems that can function to control autonomous vehicle 102. Internal computing system 124 can receive inputs from passengers and/or human drivers within autonomous vehicle 102.

Internal computing system 124 can include control service 126, which functions to control operation of autonomous vehicle 102 via, for example, the mechanical systems as well as interacting with sensor systems 108. Control service 126 can interact with other systems (e.g., constraint service 128, communication service 130, latency service 132 and internal computing system 124) to control operation of autonomous vehicle 102.

Internal computing system 124 can also include constraint service 128, which functions to control operation of autonomous vehicle 102 through application of rule-based restrictions or other constraints on operation of autonomous vehicle 102. Constraint service 128 can interact with other systems (e.g., control service 126, communication service 130, latency service 132, user interface service 134) to control operation of autonomous vehicle 102.

Internal computing system 124 can further include communication service 130, which functions to control transmission of signals from, and receipt of signals by, autonomous vehicle 102. Communication service 130 can interact with safety system 122 to provide the waveform sensing, amplification and repeating functionality described herein. Communication service 130 can interact with other systems (e.g., control service 126, constraint service 128, latency service 132 and user interface service 134) to control operation of autonomous vehicle 102.

Internal computing system 124 can also include latency service 132, which functions to provide and/or utilize timestamp information on communications to help manage and coordinate time-sensitive operations within internal computing system 124 and autonomous vehicle 102. Thus, latency service 132 can interact with other systems (e.g., control service 126, constraint service 128, communication service 130, user interface service 134) to control operation of autonomous vehicle 102.

Internal computing system 124 can further include user interface service 134, which functions to provide information to, and receive inputs from, human passengers within autonomous vehicle 102. This can include, for example, receiving a desired destination for one or more passengers and providing status and timing information with respect to arrival at the desired destination. User interface service 134 can interact with other systems (e.g., control service 126, constraint service 128, communication service 130, latency service 132) to control operation of autonomous vehicle 102.

Internal computing system 124 can function to send and receive signals from autonomous vehicle 102 regarding reporting data for training and evaluating machine learning algorithms, requesting assistance from a remote computing system or a human operator, software updates, rideshare information (e.g., pickup and/or dropoff requests and/or locations), etc.

In some examples described herein autonomous vehicle 102 (or another device) may be described as collecting data corresponding to surrounding vehicles. This data may be collected without associated identifiable information from these surrounding vehicles (e.g., without license plate numbers, make, model, and the color of the surrounding vehicles). Accordingly, the techniques mentioned here can because for the beneficial purposes described, but without the need to store potentially sensitive information of the surrounding vehicles.

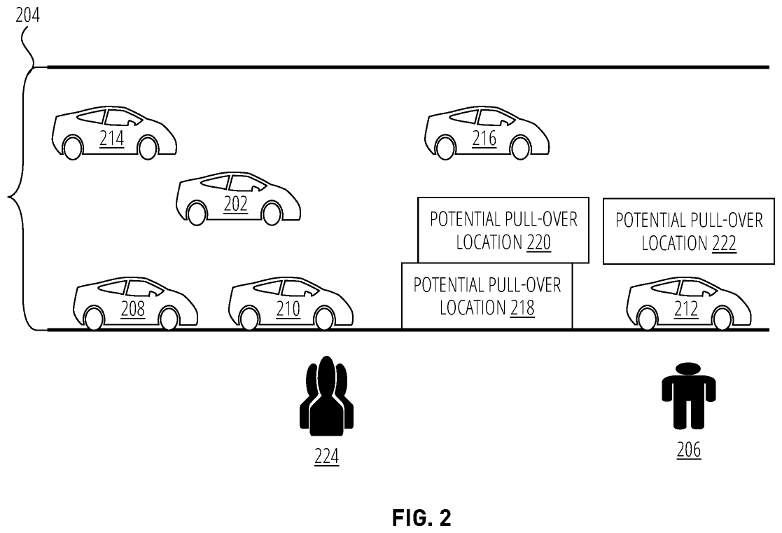

FIG. 2 is an example environment in which an autonomous vehicle may select a pull-over location to pick up a passenger. In the example of FIG. 2, autonomous vehicle 202 is traveling on road 204 to pick up passenger 206. The example of FIG. 2 is just one simple example of a pickup involving, for example, an autonomous vehicle providing a rideshare service. Autonomous vehicle 202 may attempt a pull-over maneuver for many other reasons including, for example, an emergency stop, to allow an emergency vehicle to pass, to return to a designated parking/storage location, to return to an owner/controller, etc.

In the example of FIG. 2, vehicles and other obstacles exist on road 204 and autonomous vehicle 202 must safely avoid one or more of the other vehicles and obstacles. Automobiles 208, 210 and 212 may be parked vehicles that are on the same side of road 204 as passenger 206. Automobiles 214 and 216 may be traveling along road 204 with autonomous vehicle 202. Autonomous vehicle 202 can evaluate various potential pull-over locations (e.g., potential pull-over location 218, potential pull-over location 220, potential pull-over location 222) to pick up passenger 206. Pedestrians 224 may also be a consideration when evaluating potential pull-over locations.

As described in greater detail below, autonomous vehicle 202 can attempt to identify the pull-over location that results in minimal impact on traffic and is relatively close to passenger 206. The approach to identifying the desired pull-over location can be based on use of previously executed offline simulations to provide a guiding structure that autonomous vehicle 202 can use to search for pull-over locations having similar characteristics. In an example, the simulations are based on reinforcement learning (RL) techniques, which are described in greater detail below.

In general, autonomous vehicle 202 searches for locations (e.g., through scoring) that are similar to where simulations determined were the best pull-over locations. Thus, many simulations can be run offline to evaluate many different scenarios and the intelligence gathered from those simulations can be provided to autonomous vehicle 202 to be used as the basis for real-time decision making, which can result in a more sophisticated analysis and potentially improved selection of pull-over locations.

Various factors can be considered in the simulation and pull-over location selection processes including, for example, effects on other cars, how easy (or difficult) it will be for passenger 206 to get in autonomous vehicle 202. Various inconveniences for passenger 206 can be considered and factored in to the evaluation of selecting the pull-over location. For example, it may be undesirable to require passenger 206 to cross lanes of traffic to enter autonomous vehicle 202.

In an example, real world conditions as observed by autonomous vehicle 202 can be compared with one or more simulation results to determine if the simulation results can provide guidance with respect to the current observed situation. That is, if the current situation is similar enough to one or more of the simulation results, actions (or a subset thereof) utilized in the simulation can be executed by autonomous vehicle 202 in the current situation. Thus, autonomous vehicle 202 can have a larger library of knowledge to utilize in real world situations that would otherwise be possible without the simulation result information.

The approach to pull-over location selection described herein can thus provide a dynamic solution to determining where autonomous vehicle 202 should pull over. Further, the approach can provide a higher-level and more flexible structure for pull-over location evaluation and selection than is available using techniques that do not incorporate simulation information.

In an example, the output from the offline simulation process is an artificial neural network with weights adjusted based on the simulations. When used in autonomous vehicle 202 the artificial neural network can continue to improve using real world data from autonomous vehicle 202. In an example, the simulations are multi-agent simulations that can include an autonomous vehicle with a passenger, an autonomous vehicle with multiple passengers, an empty autonomous vehicle, etc. The autonomous vehicle can also be simulated to function as a delivery vehicle that can deliver and/or receive payloads.

Selection of pull-over locations could be different for the delivery vehicle scenario as compared to a passenger-related scenario because, for example, a passenger may exit the front of the autonomous vehicle where a payload may be loaded/unloaded from the rear of the autonomous vehicle. Thus, parking alignment may be different for passenger situations as compared to payload situations. As another example, loading/unloading a passenger may take less time than loading/unloading a payload, so parking conditions, potential traffic blocking, potential pedestrian blocking and similar conditions can be more important in a payload situation as compared to a passenger situation. Other factors can also be considered.

Using the approach described herein, autonomous vehicle 202 may select potential pull-over location 218 as the pull-over location to pick up passenger 206. However, under certain conditions autonomous vehicle 202 may select either potential pull-over location 220 or potential pull-over location 222. For example, if pedestrians 224 are moving toward the street, autonomous vehicle 202 may opt to not block access to the street, or if pedestrians 224 are moving toward parked vehicle 210 autonomous vehicle 202 may opt to not interfere with movement of parked vehicle 210. If, for example, there is no vehicle following autonomous vehicle 202, potential pull-over location 222 can be selected and utilized without blocking traffic flow.

In an example, the final pull-over location selection can be based on a closest fit between previously performed simulation results and the real world situation as observed by autonomous vehicle 202. In another example, the final pull-over location selection can be based on a closest fit with respect to a set of simulation results combined with real world observations by autonomous vehicle 202 (or a fleet of vehicles to which autonomous vehicle 202 belongs) with respect to real world data gathered about the current situation by autonomous vehicle 202.

These are just a few simple examples to illustrate the concepts involved. Real world operation of autonomous vehicle 202 would be more complex, but could be managed using the approach described herein based on off-line simulation information to improve real world decision making by autonomous vehicle 202.

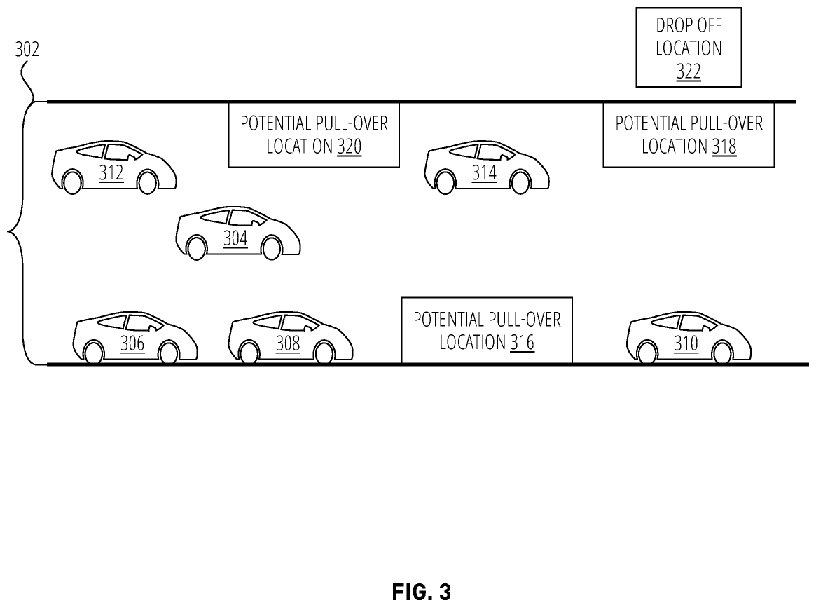

FIG. 3 is an example environment in which an autonomous vehicle may select a pull-over location to drop off a passenger. In the example of FIG. 3, autonomous vehicle 202 is traveling on road 204 to pick up passenger 206. The example of FIG. 3 is just one simple example of a drop off involving, for example, an autonomous vehicle providing a rideshare service.

In an example, passenger drop off can be handled differently than passenger pickup because various conditions are different for drop offs as compared to pickups. For example, drop offs typically take less time because a passenger only has to exit the autonomous vehicle, whereas in a pick up scenario the passenger has to react to the approaching autonomous vehicle, verify that it is the correct autonomous vehicle and then approach the autonomous vehicle before entering. Other differences also exist.

In the example of FIG. 3, vehicles and other obstacles exist on road 302 and autonomous vehicle 304 must safely avoid one or more of the other vehicles and obstacles. Automobiles 306, 308 and 310 may be parked vehicles. Automobiles 312 and 314 may be traveling along road 302 with autonomous vehicle 304. Autonomous vehicle 304 can evaluate various potential pull-over locations (e.g., potential pull-over location 316, potential pull-over location 318, potential pull-over location 320) to drop off a passenger at drop off location 322.

Using the approach described herein, autonomous vehicle 304 can attempt to identify the pull-over location that results in minimal impact on traffic and is relatively close to drop off location 322. Various factors can be considered in the simulation and pull-over location selection processes including, for example, effects on other cars, how easy (or difficult) it will be for the passenger to exit autonomous vehicle 304 and arrive at drop off location 322. Various inconveniences for the passenger can be considered and factored in to the evaluation of selecting the pull-over location. For example, it may be undesirable to require the passenger to cross lanes of traffic to arrive at drop off location 322.

Simulation cycles can be run much more frequently than autonomous vehicle operation cycles because simulations can be run at any time of day and many simulations can be run in parallel. Thus, the “experience” or “knowledge” obtained from the simulations can be more quickly and efficiently gathered as compared to analysis of autonomous vehicle operation in the real world alone. By building a library of simulation results that are available to control systems of autonomous vehicles for comparison or matching when in real world operation, the autonomous vehicles have more and better information to draw from to make decisions when operating in the real world.

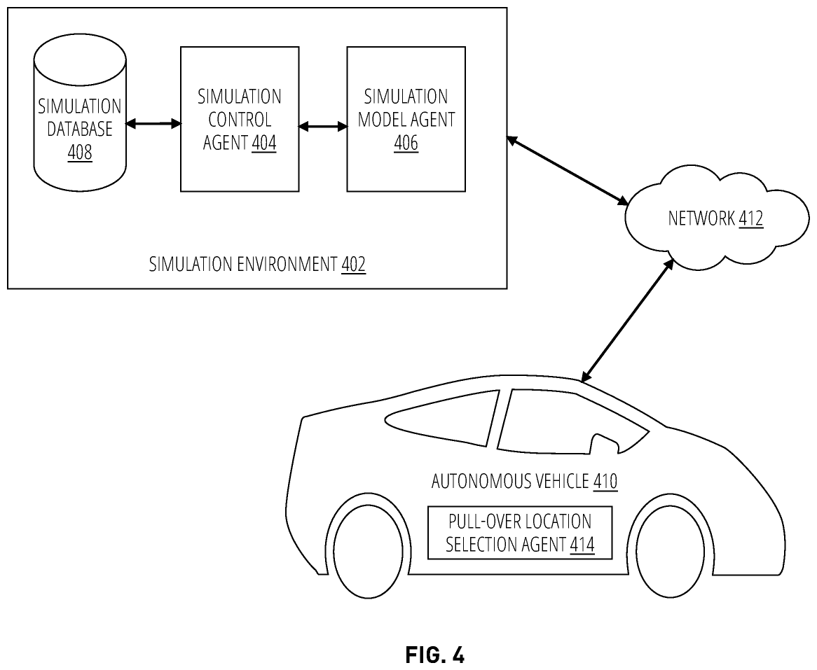

Using the approach described herein, autonomous vehicle 304 may select potential pull-over location 318 as the pull-over location to deliver the passenger to drop off location 322. However, under certain conditions autonomous vehicle 304 may selected either potential pull-over location 320 or potential pull-over location 316. For example, if there is a fire hydrant near drop off location 322 (not illustrated in FIG. 4), autonomous vehicle 304 may opt to select potential pull-over location 320. If, for example, there is no access to the side of the street where drop off location 322 is located (e.g., construction activity) autonomous vehicle 304 can select potential pull-over location 316. These are just a few simple examples to illustrate the concepts involved. Real world operation of autonomous vehicle 304 would be more complex, but could be managed using the approach described herein based on off-line simulation information to improve real world decision making by autonomous vehicle 304.

FIG. 4 is a block diagram of a simulation environment that can provide simulation information to an autonomous vehicle for assistance in selection of pull-over locations. Simulation environment 402 can represent any system (or group of systems) that can provide simulation services to generate the simulation information as described herein. Simulation environment 402 can include various computing resources including processors, co-processors, and the like that are not explicitly illustrated in FIG. 4.

Simulation environment 402 can include simulation control agent 404, simulation model agent 406 and simulation database 408 to provide the simulation information. Simulation control agent 404 controls the execution of the simulations and management of execution data, which can be stored on, for example, simulation database 408. Simulation control agent 404 can control what simulation data is provided to autonomous vehicle 410 and how that simulation information is provided.

Simulation model agent 406 can provide model information to simulation control agent 404 to cause simulation control agent 404 to perform the desired type of simulations. For example, simulation model agent 406 can cause simulation control agent 404 to perform reinforcement learning based simulations based on data from simulation database 408 and/or data from autonomous vehicle 410 (or other autonomous vehicles). In some examples, the simulations can be multi-agent simulations with at least an autonomous vehicle and a passenger. Multiple passengers and/or ride pooling can also be supported in the simulations.

In an example, the following basic set of inputs are utilized for simulations: poses and velocity information for all entities in a scene (e.g., autonomous vehicles, passengers, potential passengers, other autonomous vehicles, human-operated vehicles, bicycles, motorcycles, animals), map information (e.g., positions on lanes, position of traffic lights), and the desired pick up and/or drop off location(s). Alternative input sets can also be supported.

Once the desired number of simulations are completed, simulation control agent 404 can cause simulation information to be transmitted to autonomous vehicle 410 over, for example, network 412. In an example, the simulation information includes at least an artificial neural network architecture with weights adjusted based on the simulations.

Autonomous vehicle 410 can receive the simulation information from simulation environment 402 via network 412 and can provide the simulation information to pull-over location selection agent 414. Pull-over location selection agent 414 can use the simulation information to evaluate potential pull-over locations in the manner described herein and cause the control systems of autonomous vehicle 410 to navigate to a selected pull-over location.

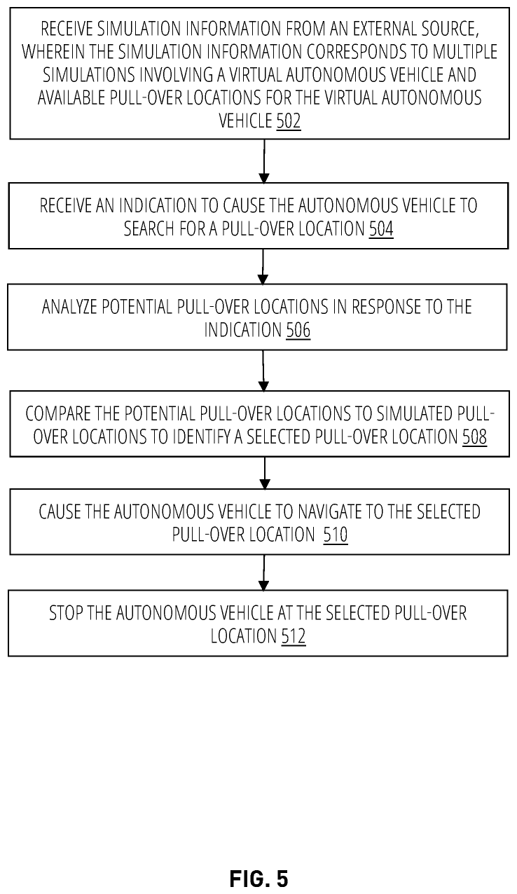

FIG. 5 is a flow diagram for one technique for selection of a pull-over location for an autonomous vehicle. The functionality described with respect to FIG. 5 can be provided by an autonomous vehicle operating in a driving environment in which other road users (e.g., other autonomous vehicle, human-operated vehicles, pedestrians, bicycles) can also operate.

One or more control components of the autonomous vehicle (e.g., autonomous vehicle control systems 106) can receive simulation information that is based on multiple simulations involving a virtual autonomous vehicle and available pull-over locations for the virtual autonomous vehicle, 502. The simulations can be accomplished using, for example, reinforcement learning techniques.

One or more control components of the autonomous vehicle can receive an indication to cause the autonomous vehicle to search for a pull-over location, 504. In a rideshare example, the indication can be a request for a ride from a passenger to the rideshare service that can be routed to a specific autonomous vehicle. In a delivery example, the indication can be a request to a cargo/delivery/courier service that can be routed to the autonomous vehicle based on, for example, geographic location, vehicle size, etc. As another example, the autonomous vehicle can utilize sensors to detect a person hailing the autonomous vehicle by, for example, waving their hand or flashing a cellphone light, etc.

One or more control components of the autonomous vehicle can analyze potential pull-over locations in response to the indication, 506. The autonomous vehicle can utilize onboard sensors (e.g., sensors 104) as well as additional information (e.g., map information, global positioning system information) to identify potential pull-over locations. A list of candidate pull-over locations can be made for analysis with respect to the received sensor information.

One or more control components of the autonomous vehicle can compare the potential pull-over locations to simulated pull-over locations to identify a selected pull-over location, 508. The potential pull-over locations can be analyzed with respect to simulation information and/or information gathered by sensors of the autonomous vehicle. In some examples, individual autonomous vehicles in a fleet of autonomous vehicles can share information. On the basis of the analysis a pull-over location can be selected.

One or more control components of the autonomous vehicle can cause the autonomous vehicle to navigate to the selected pull-over location, 510. With the location of the selected pull-over location and the sensor information regarding the current operating environment, the autonomous vehicle can navigate to the selected pull-over location.

One or more control components of the autonomous vehicle can stop the autonomous vehicle at the selected pull-over location, 512. The autonomous vehicle can stop in the selected pull-over location. In an example, the autonomous vehicle can take an action to notify a waiting passenger or party that has cargo to be picked up by, for example, honking a horn and/or flashing lights.

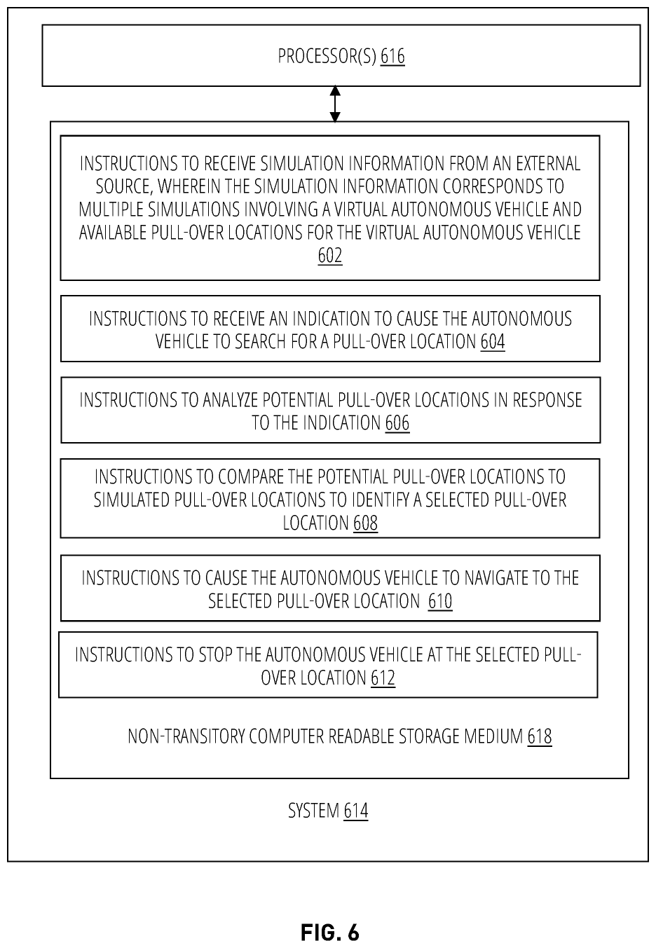

FIG. 6 is a block diagram of one example of a processing system that can provide selection of a pull-over location for an autonomous vehicle. In one example, system 614 can be part of an autonomous vehicle (e.g., autonomous vehicle 102 as part of internal computing system 124) that utilizes various sensors including radar sensors. In other examples, system 614 can be part of a human-operated vehicle having an advanced driver assistance system (ADAS) that can utilized various sensors including radar sensors.

In an example, system 614 can include processor(s) 616 and non-transitory computer readable storage medium 618. Non-transitory computer readable storage medium 618 may store instructions 602, 604, 606, 608, 610 and 612 that, when executed by processor(s) 616, cause processor(s) 616 to perform various functions. Examples of processor(s) 616 may include a microcontroller, a microprocessor, a central processing unit (CPU), a graphics processing unit (GPU), a data processing unit (DPU), an application-specific integrated circuit (ASIC), an field programmable gate array (FPGA), a system on a chip (SoC), etc. Examples of a non-transitory computer readable storage medium 618 include tangible media such as random access memory (RAM), read-only memory (ROM), electrically erasable programmable read-only memory (EEPROM), flash memory, a hard disk drive, etc.

Instructions 602 cause processor(s) 616 to receive simulation information that is based on multiple simulations involving a virtual autonomous vehicle and available pull-over locations for the virtual autonomous vehicle. The simulations can be accomplished using, for example, reinforcement learning techniques.

Instructions 604 cause processor(s) 616 to receive an indication to cause the autonomous vehicle to search for a pull-over location. The indication to pull over can be received by the autonomous vehicle from a remote source (e.g., over a network connection) in response to a passenger requesting a ride or from a passenger of the autonomous vehicle indicating a desired to exit the autonomous vehicle.

Instructions 606 cause processor(s) 616 to analyze potential pull-over locations in response to the indication. The autonomous vehicle can utilize onboard sensors (e.g., sensors 104) as well as additional information (e.g., map information, global positioning system information) to identify potential pull-over locations. A list of candidate pull-over locations can be made for analysis with respect to the received sensor information.

Instructions 608 cause processor(s) 616 to compare the potential pull-over locations to simulated pull-over locations to identify a selected pull-over location. The potential pull-over locations can be analyzed with respect to simulation information and/or information gathered by sensors of the autonomous vehicle. In some examples, individual autonomous vehicles in a fleet of autonomous vehicles can share information. On the basis of the analysis a pull-over location can be selected.

Instructions 610 cause processor(s) 616 to cause the autonomous vehicle to navigate to the selected pull-over location. With the location of the selected pull-over location and the sensor information regarding the current operating environment, the autonomous vehicle can navigate to the selected pull-over location.

Instructions 612 cause processor(s) 616 to stop the autonomous vehicle at the selected pull-over location. The autonomous vehicle can stop in the selected pull-over location. In an example, the autonomous vehicle can take an action to notify a waiting passenger or party that has cargo to be picked up by, for example, honking a horn and/or flashing lights.

In the description above, for the purposes of explanation, numerous specific details are set forth in order to provide a thorough understanding of the described examples. It will be apparent, however, to one skilled in the art that examples may be practiced without some of these specific details. In other instances, well-known structures and devices are shown in block diagram form. There may be intermediate structures between illustrated components. The components described or illustrated herein may have additional inputs or outputs that are not illustrated or described.

Various examples may include various processes. These processes may be performed by hardware components or may be embodied in computer program or machine-executable instructions, which may be used to cause processor or logic circuits programmed with the instructions to perform the processes. Alternatively, the processes may be performed by a combination of hardware and software.

Portions of various examples may be provided as a computer program product, which may include a non-transitory computer-readable medium having stored thereon computer program instructions, which may be used to program a computer (or other electronic devices) for execution by one or more processors to perform a process according to certain examples. The computer-readable medium may include, but is not limited to, magnetic disks, optical disks, read-only memory (ROM), random access memory (RAM), erasable programmable read-only memory (EPROM), electrically-erasable programmable read-only memory (EEPROM), magnetic or optical cards, flash memory, or other type of computer-readable medium suitable for storing electronic instructions. Moreover, examples may also be downloaded as a computer program product, wherein the program may be transferred from a remote computer to a requesting computer. In some examples, non-transitory computer readable storage medium 618 has stored thereon data representing sequences of instructions that, when executed by a processor(s) 616, cause the processor(s) 616 to perform certain operations.

Reference in the specification to “an example,” “one example,” “some examples,” or “other examples” means that a particular feature, structure, or characteristic described in connection with the examples is included in at least some examples, but not necessarily all examples. Additionally, such feature, structure, or characteristics described in connection with “an example,” “one example,” “some examples,” or “other examples” should not be construed to be limited or restricted to those example(s), but may be, for example, combined with other examples. The various appearances of “an example,” “one example,” or “some examples” are not necessarily all referring to the same examples.

What is claimed is:

1. An autonomous vehicle comprising:
sensor systems to detect characteristics of an operating environment;
kinematic control systems to provide kinematic controls to the autonomous vehicle;
a vehicle control system coupled with the sensor systems and with the kinematic control systems, the vehicle control system to:
receive simulation information from an external source, wherein the simulation information corresponds to multiple simulations involving a virtual autonomous vehicle and available pull-over locations for the virtual autonomous vehicle;
receive an indication to cause the autonomous vehicle to search for a pull-over location;
analyze potential pull-over locations in response to the indication;
compare the potential pull-over locations to simulated pull-over locations to identify a selected pull-over location;
cause the autonomous vehicle to navigate to the selected pull-over location; and
cause the autonomous vehicle to stop at the selected pull-over location.

2. The autonomous vehicle of claim 1 wherein the vehicle control system is further configured to:
collect operational information for selection and use of the pull-over location; and
transmitting the collected operational information to a repository for use in subsequent simulations.

3. The autonomous vehicle of claim 1 wherein comparing the potential pull-over locations to simulated pull-over locations to identify a selected pull-over location further comprises:
utilizing weight values received as part of the simulation information in an artificial neural network (ANN) to compare the potential pull-over locations to simulated pull-over locations;
utilizing output values from the artificial neural network to identify the selected pull-over location; and
provide identifying information corresponding to the selected pull-over location to the vehicle control system.

4. The autonomous vehicle of claim 1 wherein the simulation comprises a reinforcement learning (RL) based simulation.

5. The autonomous vehicle of claim 1 wherein the pull-over location is for a passenger of the autonomous vehicle is disembark the autonomous vehicle.

6. The autonomous vehicle of claim 1 wherein the pull-over location is for the autonomous vehicle to accept a passenger.

7. A non-transitory computer-readable medium having stored thereon instructions that, when executed by one or more processors, are configurable to cause the processors to:
receive simulation information from an external source, wherein the simulation information corresponds to multiple simulations involving a virtual autonomous vehicle and available pull-over locations for the virtual autonomous vehicle;
receive an indication to cause the autonomous vehicle to search for a pull-over location;
analyze potential pull-over locations in response to the indication;
compare the potential pull-over locations to simulated pull-over locations to identify a selected pull-over location;
cause the autonomous vehicle to navigate to the selected pull-over location; and
cause the autonomous vehicle to stop at the selected pull-over location.

8. The non-transitory computer-readable medium of claim 7 wherein the one or more hardware processors are further configured to:
collect operational information for selection and use of the pull-over location; and
transmitting the collected operational information to a repository for use in subsequent simulations.

9. The non-transitory computer-readable medium of claim 7 wherein comparing the potential pull-over locations to simulated pull-over locations to identify a selected pull-over location further comprises:
utilizing weight values received as part of the simulation information in an artificial neural network (ANN) to compare the potential pull-over locations to simulated pull-over locations;
utilizing output values from the artificial neural network to identify the selected pull-over location; and
provide identifying information corresponding to the selected pull-over location to a vehicle control system of the autonomous vehicle.

10. The non-transitory computer-readable medium of claim 7 wherein the simulation comprises a reinforcement learning (RL) based simulation.

11. The non-transitory computer-readable medium of claim 7 wherein the pull-over location is for a passenger of the autonomous vehicle is disembark the autonomous vehicle.

12. The non-transitory computer-readable medium of claim 7 wherein the pull-over location is for the autonomous vehicle to accept a passenger.

13. An autonomous vehicle control system comprising:
a memory system; and
one or more hardware processors coupled with the memory system, the one or more processors to:
receive simulation information from an external source, wherein the simulation information corresponds to multiple simulations involving a virtual autonomous vehicle and available pull-over locations for the virtual autonomous vehicle;
receive an indication to cause the autonomous vehicle to search for a pull-over location;
analyze potential pull-over locations in response to the indication;
compare the potential pull-over locations to simulated pull-over locations to identify a selected pull-over location;
cause the autonomous vehicle to navigate to the selected pull-over location; and
cause the autonomous vehicle to stop at the selected pull-over location.

14. The autonomous vehicle control system of claim 13 wherein the one or more hardware processors are further configured to:
collect operational information for selection and use of the pull-over location; and
transmitting the collected operational information to a repository for use in subsequent simulations.

15. The autonomous vehicle control system of claim 13 wherein comparing the potential pull-over locations to simulated pull-over locations to identify a selected pull-over location further comprises:
utilizing weight values received as part of the simulation information in an artificial neural network (ANN) to compare the potential pull-over locations to simulated pull-over locations;
utilizing output values from the artificial neural network to identify the selected pull-over location; and
provide identifying information corresponding to the selected pull-over location to a vehicle control system of the autonomous vehicle.

16. The autonomous vehicle control system of claim 13 wherein the simulation comprises a reinforcement learning (RL) based simulation.

17. The autonomous vehicle control system of claim 13 wherein the pull-over location is for a passenger of the autonomous vehicle is disembark the autonomous vehicle.

18. The autonomous vehicle control system of claim 13 wherein the pull-over location is for the autonomous vehicle to accept a passenger.
